(19) United States
(12) Patent Application Publication
(10) Pub. No.: US 2016/0163704 A1
(43) Pub. Date: Jun. 9, 2016

(54) SEMICONDUCTOR DEVICE HAVING HETEROGENEOUS STRUCTURE AND METHOD FORMING THE SAME

(71) Applicant: JAEHOON LEE, Suwon-si (KR)

(72) Inventor: JAEHOON LEE, Suwon-si (KR)

(21) Appl. No.: 14/958,078

(22) Filed: Dec. 3, 2015

(30) Foreign Application Priority Data
Dec. 4, 2014 (KR) 10-2014-0173277

(51) Int. Cl. H01L 27/092; H01L 29/778; H01L 29/10

(52) U.S. Cl. CPC H01L 27/0922; H01L 29/1054; H01L 29/7786; H01L 27/0928

(57) ABSTRACT

A semiconductor device is provided as follows. A first buffer layer is disposed on a substrate including NMOS and PMOS regions. A first drain and a first source are disposed on the first buffer layer and have heterogeneous structures. A first channel is disposed between the first drain and the first source. A first gate electrode is disposed on the first channel. A second drain and a second source are disposed on the first buffer layer. A second channel is disposed between the second drain and the second source. The second channel includes a different material from the first channel. A second gate electrode is disposed on the second channel. The first drain, the first source, the first channel and the first gate electrode are disposed in the NMOS region. The second drain, the second source, the second channel and the second gate electrode are disposed in the PMOS region.

### CROSS-REFERENCE TO RELATED APPLICATION

This application claims priority under 35 U.S.C. §119 to Korean Patent Application No. 10-2014-0173277 filed on Dec. 4, 2014, the disclosure of which is incorporated by reference herein in its entirety.

### TECHNICAL FIELD

The present inventive concept relates to a semiconductor device having a heterogeneous structure and a method of forming the same.

### DISCUSSION OF RELATED ART

As transistors scale down in size, turn-on currents thereof decrease. The decrease in turn-on currents degrades performance of the transistors.

### SUMMARY

According to an example embodiment of the present embodiment, a semiconductor device is provided as follows. A first buffer layer is disposed on a substrate including an NMOS region and a PMOS region. A first drain and a first source are disposed on the first buffer layer and spaced apart from each other. Each of the first drain and the source has a heterogeneous structure. A first channel is disposed between the first drain and the first source. A first gate electrode is disposed on the first channel. A second drain and a second source are disposed on the first buffer layer and spaced apart from each other. A second channel is disposed between the second drain and the second source. The second channel includes a different material from the first channel. A second gate electrode is disposed on the second channel. The first drain, the first source, the first channel, and the first gate electrode are disposed in the NMOS region. The second drain, the second source, the second channel, and the second gate electrode are disposed in the PMOS region.

According to an example embodiment of the present inventive concept, a semiconductor device is provided as follows. A buffer layer is disposed on a substrate. A drain and a source are disposed on the buffer layer and spaced apart from each other. Each of the drain and the source is a heterogeneous structure. A channel is disposed between the drain and the source and includes a different semiconductor material from the drain and the source. A gate electrode is disposed on the channel.

According to an example embodiment of the present inventive concept, a semiconductor device is provided as follows. A first buffer layer is disposed on a substrate. A second buffer layer is disposed on the first buffer layer. A stressor is interposed between the first buffer layer and a second buffer layer. A drain, a source, and a channel are disposed on the upper buffer layer. Each of the drain, the source and the channel is in contact with the second buffer layer. A gate electrode is disposed on the channel. The first buffer layer includes an AlxGa1-xN (0<X≦1) graded structure with an Al content increasing downwardly toward the substrate and decreasing upwardly toward the stressor. The channel is interposed between the drain and the source.

According to an example embodiment of the present inventive concept, a method of forming a semiconductor device is provided as follows. A first buffer layer is formed on a substrate including an NMOS region and a PMOS region. A first drain and a first source are formed on the first buffer layer. The first drain and the first source are spaced apart from each other and each of the first drain and the first source has a heterogeneous structure. A first channel is formed between the first drain and the first source. A second buffer layer is formed on the first buffer layer. A second drain and a second source are formed on the second buffer layer. A second channel is formed on the second buffer layer. The second channel includes a different material from the first channel and is disposed between the second drain and the second source. A first gate electrode is formed on the first channel. A second gate electrode is formed on the second channel. The first drain, the first source, the first channel, and the first gate electrode are formed in the NMOS region. The second drain, the second source, the second channel and the second gate electrode are formed in the PMOS region. The first buffer layer is disposed in the NMOS region and the PMOS region, and the second buffer layer is disposed in the PMOS region.

According to an example embodiment of the present inventive concept, a semiconductor device is provided as follows. A first buffer layer is disposed in an NMOS region and a PMOS region of a substrate. A second buffer layer is disposed in the PMOS region only. A first transistor is disposed on a first portion of the first buffer layer, wherein the first portion is disposed in the NMOS region. A second transistor is disposed on the second buffer layer. The first transistor includes a first source/drain having a layered, heterogeneous structure and the second transistor includes a second source/drain. An upper surface of the first source/drain is higher than an upper surface of the second source/drain.

### BRIEF DESCRIPTION OF THE DRAWINGS

These and other features of the inventive concept will become more apparent by describing in detail example embodiments thereof with reference to the accompanying drawings of which:

FIGS. 1 to 18 are cross-sectional views of semiconductor devices in accordance with example embodiments of the present inventive concept;

FIGS. 19 to 43 are cross-sectional views of methods of forming semiconductor devices in accordance with example embodiments of the present inventive concept; and

FIGS. 44 and 45 are system block diagrams of electronic apparatuses in accordance with example embodiments of the present inventive concept.

Although corresponding plan views and/or perspective views of some cross-sectional view(s) may not be shown, the cross-sectional view(s) of device structures illustrated herein provide support for a plurality of device structures that extend along two different directions as would be illustrated in a plan view, and/or in three different directions as would be illustrated in a perspective view. The two different directions may or may not be orthogonal to each other. The three different directions may include a third direction that may be orthogonal to the two different directions. The plurality of device structures may be integrated in a same electronic device. For example, when a device structure (e.g., a memory cell structure or a transistor structure) is illustrated in a cross-sectional view, an electronic device may include a plurality of the device structures (e.g., memory cell structures or transistor structures), as would be illustrated by a plan view of the electronic device. The plurality of device structures may be arranged in an array and/or in a two-dimensional pattern.

### DETAILED DESCRIPTION OF EXAMPLE EMBODIMENTS

Example embodiments of the inventive concept will be described below in detail with reference to the accompanying drawings. However, the inventive concept may be embodied in different forms and should not be construed as limited to the embodiments set forth herein. In the drawings, the thickness of layers and regions may be exaggerated for clarity. It will also be understood that when an element is referred to as being “on” another element or substrate, it may be directly on the other element or substrate, or intervening layers may also be present. It will also be understood that when an element is referred to as being “coupled to” or “connected to” another element, it may be directly coupled to or connected to the other element, or intervening elements may also be present. Like reference numerals may refer to the like elements throughout the specification and drawings.

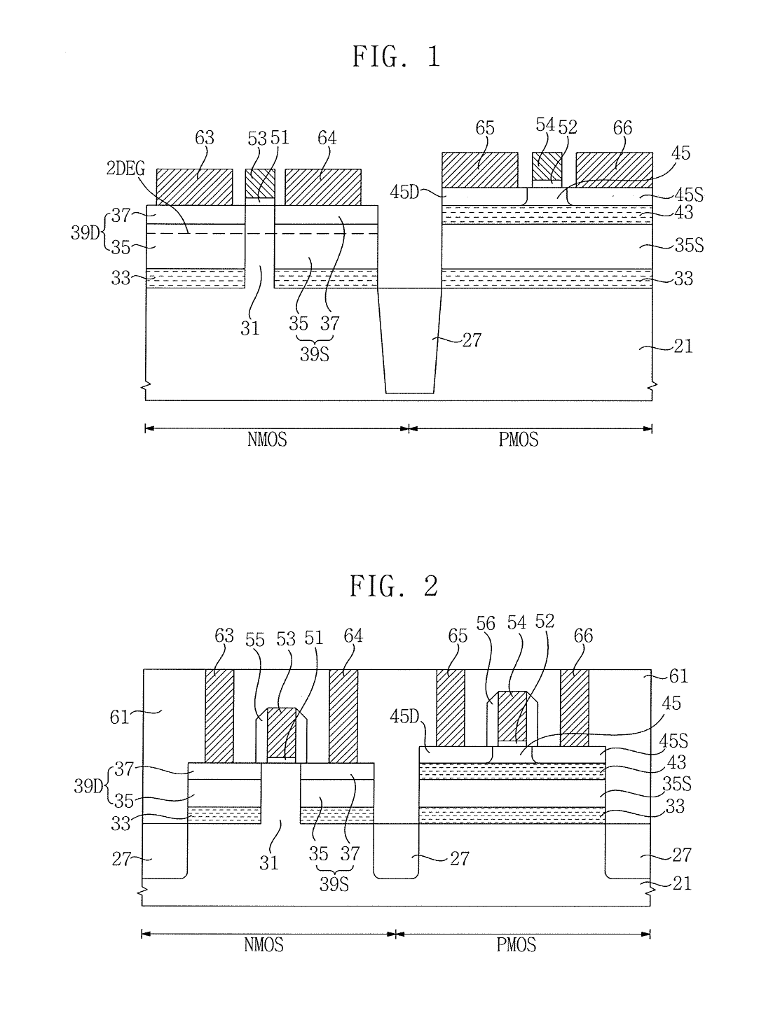

FIGS. 1 to 18 are cross-sectional views of semiconductor devices in accordance with example embodiments of the present inventive concept.

Referring to FIG. 1, a semiconductor device in accordance with an example embodiment of the present inventive concept includes a device isolation layer 27, a first channel 31, a buffer layer 33, a first drain 39D, a first source 39S, a first gate dielectric layer 51, a first gate electrode 53, a stressor 35S, an upper buffer layer 43, a second channel 45, a second drain 45D, a second source 45S, a second gate dielectric layer 52, a second gate electrode 54, and contact plugs 63, 64, 65, and 66, which are formed on a substrate 21 including an NMOS region and a PMOS region. Hereinafter, a source/drain may refer to a source or a drain.

Each of the first drain 39D and the first source 39S includes a first semiconductor layer 35 and a second semiconductor layer 37. The first semiconductor layer 35 and the second semiconductor layer 37 constitute a heterogeneous structure. The contact plugs 63, 64, 65, and 66 include a first contact plug 63, a second contact plug 64, a third contact plug 65, and a fourth contact plug 66. The first channel 31, the first drain 39D, the first source 39S, the first gate dielectric layer 51, the first gate electrode 53, the first contact plug 63, and the second contact plug 64 are formed in the NMOS region. The stressor 35S, the upper buffer layer 43, the second channel 45, the second drain 45D, the second source 45S, the second gate dielectric layer 52, the second gate electrode 54, the third contact plug 65, and the fourth contact plug 66 are formed in the PMOS region. The contact plugs 63, 64, 65, and 66 may include a metal layer, a metal nitride layer, a metal oxide layer, a metal silicide layer, a polysilicon layer, a semiconductor layer, an ohmic contact layer, or a combination thereof.

The substrate 21 may include Si, Ge, silicon on insulator (SOI), sapphire, glass, AlN, SiC, GaAs, InAs, graphene, carbon nanotubes (CNT), a plastic, or a combination thereof. For example, the substrate 21 may be a single crystalline silicon wafer containing p-type impurities. The first channel 31 may include Si, Ge, GaN, InN, GaAs, InAs, AlGaAs, InSb, InP, graphene, CNT, MoS2, or a combination thereof. For example, the first channel 31 may include single crystalline silicon containing p-type impurities.

The first channel 31 may be confined to a portion of the substrate 21. The first channel 31 may be integrated with the substrate 21. The first channel 31 and the substrate 21 may have the same and continuous crystal structure. The first channel 31 may be extended beyond a lower surface of the buffer layer 33. Alternatively, the first channel 31 may be confined between the first drain 39D and the first source 39S. An upper surface of the first channel 31 may be formed substantially to be coplanar with an upper surface of the second semiconductor layer 37. The first channel 31 may include a different semiconductor layer from the first drain 39D and the first source 39S.

The first drain 39D is spaced apart from the first source 39S. Each of the first drain 39D and the first source 39S includes a heterogeneous structure. Each of the first drain 39D and the first source 39S may include an AlGaN/GaN heterogeneous structure, an AlN/GaN heterogeneous structure, a GaN/InN heterogeneous structure, a AlGaS/GaS heterogeneous structure, an InGaS/InP heterogeneous structure, a Si/Ge heterogeneous structure, a TiO2/SrTiO3 heterogeneous structure, a Bi2/Se3 heterogeneous structure, a LaAlO3/SrTiO3 heterogeneous structure, a graphene/MoS2 heterogeneous structure, a graphene/BN/graphene heterogeneous structure, or a BN/graphene/BN heterogeneous structure. In an example embodiment, the back slash “/” used in the above-listed heterogeneous structure may indicate to an interface between two material layers divided by the back slash “/”. A material layer in front of the back slash “/” is disposed higher than a material layer behind the back slash “/” in a layered, heterogeneous structure of the first source/drain 39S and 39D. The first semiconductor layer 35 is in contact with a side surface of the first channel 31. An upper surface of the first semiconductor layer 35 is lower than the upper surface of the first channel 31. The first semiconductor layer 35 includes a material having a smaller lattice constant than the first channel 31. Due to the configuration of the first semiconductor layer 35, a tensile stress may be applied to the first channel 31. For example, the first semiconductor layer 35 may include GaN, and the second semiconductor layer 37 may include AlGaN. The second semiconductor layer 37 is in contact with the side surface of the first channel 31.

A two-dimensional high mobility electron gas (2DEG) may be formed in each of the first drain 39D and the first source 39S. For example, the two-dimensional electron gas (2DEG) may be formed in the first semiconductor layer 35 adjacent to an interface between the first semiconductor layer 35 and the second semiconductor layer 37. An inversion channel may be formed in the first channel 31. The two-dimensional high mobility electron gas (2DEG) of the first drain 39D and the two-dimensional high mobility electron gas (2DEG) of the first source 39S may be connected through the inversion channel of the first channel 31.

The buffer layer 33 is formed between the substrate 21 and the first drain 39D. The buffer layer 33 is also formed between the substrate 21 and the first source 39S. The buffer layer 33 is in contact with the substrate 21, the first drain 39D, and the first source 39S. A side surface of the buffer layer 33 is in contact with the side surface of the first channel 31. The buffer layer 33 may include an AlₓGa₁₋ₓN (0<X≦1) graded structure with an Al content or doping increasing downwardly toward the substrate 21, and decreasing upwardly toward the first drain 39D and the first source 39S. A thickness of the buffer layer 33 is smaller than that of the first semiconductor layer 35. The present inventive concept is not limited thereto, and the thickness of the buffer layer 33 may be greater than the first semiconductor layer 35.

For example, the buffer layer 33 may include sequentially stacked first to sixth layers. A first layer of the buffer layer 33 may be an AlN layer and the lowermost layer of which a lower surface is in contact with the substrate 21. A second layer of the buffer layer 33 may be an AlₓGa₁₋ₓN (0.7≦X≦1) layer and formed on the first layer. A third layer of the buffer layer 33 may be an AlₓGa₁₋ₓN (0.5≦X<0.7) layer and formed on the second layer. A fourth layer of the buffer layer 33 may be an AlₓGa₁₋ₓN (0.3≦X<0.5) layer and formed on the third layer. A fifth layer of the buffer layer 33 may be an AlₓGa₁₋ₓN (0.05≦X<0.3) layer and formed on the fourth layer. A sixth layer of the buffer layer 33 may be an AlₓGa₁₋ₓN (0<X<0.05) layer and formed on the fifth layer. The sixth layer of the buffer layer 33 is the uppermost layer which is in contact with a lower surface of the first semiconductor layer 35.

According to example embodiments of the present inventive concept, electron mobility may increase due to the configuration of the first channel 31, the first drain 39D, and the first source 39S. The buffer layer 33 may function to prevent generation of defects due to a difference in lattice constant between the first semiconductor layer 35 and the substrate 21. The buffer layer 33 may function to prevent generation of cracks in the first drain 39D and the first source 39S.

The stressor 35S may include a material having a different lattice constant from the second channel 45. The stressor 35S may include a material having a smaller lattice constant than the second channel 45. The stressor 35S may include a different material from the second channel 45. The stressor 35S may include substantially the same material as the first semiconductor layer 35. A thickness of the stressor 35S may be substantially the same as that of the first semiconductor layer 35. The stressor 35S may be simultaneously formed with the first semiconductor layer 35. For example, the stressor 35S may include GaN.

The buffer layer 33 is interposed between the substrate 21 and the stressor 35S. A lower surface of the stressor 35S is in contact with the buffer layer 33. A thickness of the buffer layer 33 is smaller than the thickness of the stressor 35S. In an example embodiment, the thickness of the buffer layer 33 may be greater than the thickness of the stressor 35S. The buffer layer 33 may include an AlₓGa₁₋ₓN (0<X≦1) graded structure with an Al content increasing downwardly toward the substrate 21 and decreasing upwardly toward the stressor 35S.

The upper buffer layer 43 is formed on the stressor 35S. The second channel 45, the second drain 45D, and the second source 45S are formed on the upper buffer layer 43. The upper buffer layer 43 is in contact with the stressor 35S, the second channel 45, the second drain 45D, and the second source 45S. A thickness of the upper buffer layer 43 is smaller than the thickness of the stressor 35S. In an example embodiment, the thickness of the upper buffer layer 43 may be greater than the thickness of the stressor 35S. The upper buffer layer 43 may be formed using a method similar to method of forming the buffer layer 33. The upper buffer layer 43 may include an AlₓGa₁₋ₓN (0<X≦1) graded structure with an Al content increasing downwardly toward the stressor 35S and decreasing upwardly toward the second channel 45, the second drain 45D, and the second source 45S.

The second channel 45 may include a different semiconductor layer from the stressor 35S. The second channel 45 may include a semiconductor layer having a different lattice constant from the stressor 35S. The second channel 45 may include a semiconductor layer having a greater lattice constant than the stressor 35S. The second channel 45 may include a different material from the substrate 21. For example, the second channel 45 may include a Ge layer containing n-type impurities.

The second drain 45D is spaced apart from the second source 45S. The second channel 45 may be confined between the second drain 45D and the second source 45S. In an example embodiment, a lower surface of the second channel 45 may be extended beyond the lower surface of the buffer layer 33. The second drain 45D and the second source 45S are in contact with the second channel 45. The second drain 45D and the second source 45S may include a Ge layer containing p-type impurities.

Due to the configuration of the stressor 35S, a compressive stress may be applied to the second channel 45. According to example embodiments of the inventive concept, due to the configuration of the second channel 45, the second drain 45D, the second source 45S, and the stressor 35S, hole mobility may increase. The buffer layer 33 may function to prevent generation of defects due to a difference in lattice constant between the stressor 35S and the substrate 21. The buffer layer 33 may function to prevent generation of cracks in the stressor 35S. The upper buffer layer 43 may function to prevent generation of defects due to a difference in lattice constant between the stressor 35S and the second channel 45, second drain 45D, and second source 45S. The upper buffer layer 43 may function to prevent generation of cracks in the stressor 35S, the second channel 45, the second drain 45D, and the second source 45S.

Referring to FIG. 2, a semiconductor device in accordance with an example embodiment of the present inventive concept includes a device isolation layer 27, a first channel 31, a buffer layer 33, a first drain 39D, a first source 39S, a first gate dielectric layer 51, a first gate electrode 53, a first spacer 55, a stressor 35S, an upper buffer layer 43, a second channel 45, a second drain 45D, a second source 45S, a second gate dielectric layer 52, a second gate electrode 54, a second spacer 56, an interlayer insulating layer 61, and contact plugs 63, 64, 65, and 66, which are formed on a substrate 21 including an NMOS region and a PMOS region.

In an example embodiment, the first channel 31, the first drain 39D, the first source 39S, the first gate dielectric layer 51 and the first gate electrode 53 may constitute a first transistor. In an example embodiment, the second channel 45, the second drain 45D, the second source 45S, the second gate dielectric layer 52 and the second gate electrode 54 may constitute a second transistor.

Each of the first drain 39D and the first source 39S includes a first semiconductor layer 35 and a second semiconductor layer 37. The first semiconductor layer 35 and the second semiconductor layer 37 may form a heterogeneous structure. The contact plugs 63, 64, 65, and 66 includes a first contact plug 63, a second contact plug 64, a third contact plug 65, and a fourth contact plug 66. The first contact plug 63 penetrates the interlayer insulating layer 61 to be connected to the first drain 39D. The second contact plug 64 penetrates the interlayer insulating layer 61 to be connected to the first source 39S. The third contact plug 65 penetrates the interlayer insulating layer 61 to be connected to the second drain 45D. The fourth contact plug 66 penetrates the interlayer insulating layer 61 to be connected to the second source 45S. The first spacer 55 is formed on a side surface of the first gate electrode 53. The second spacer 56 is formed on a side surface of the second gate electrode 54.

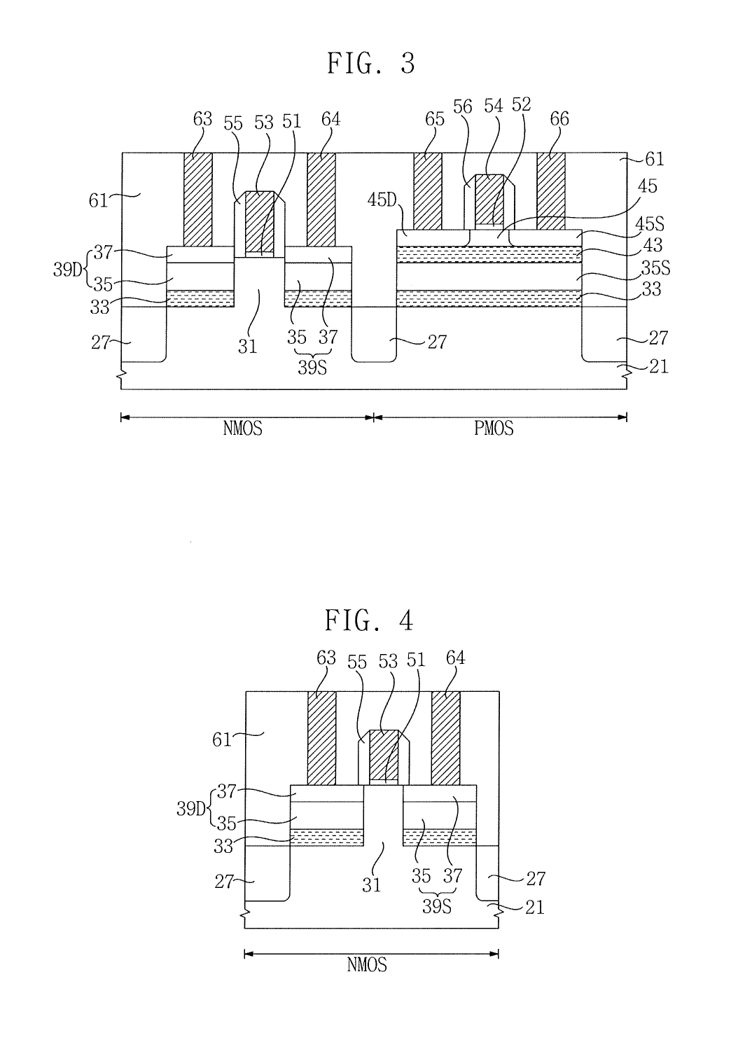

Referring to FIG. 3, an upper surface of the second semiconductor layer 37 is higher than an upper surface of first channel 31. The upper surface of the first channel 31 is lower than upper surfaces of the first drain 39D and the first source 39S. The upper surface of the first channel 31 is higher than an upper surface of the first semiconductor layer 35. The first gate dielectric layer 51 is in contact with the upper surface of the first channel 31. The upper surface of the second semiconductor layer 37 is higher than a lower surface of the first gate dielectric layer 51. The upper surface of the second semiconductor layer 37 is higher than a lower surface of the first gate electrode 53.

Referring to FIG. 4, a semiconductor device in accordance with an example embodiment of the inventive concept includes a device isolation layer 27, a first channel 31, a buffer layer 33, a first drain 39D, a first source 39S, a first gate dielectric layer 51, a first gate electrode 53, a first spacer 55, an interlayer insulating layer 61, and contact plugs 63 and 64, which are formed on a substrate 21 including an NMOS region.

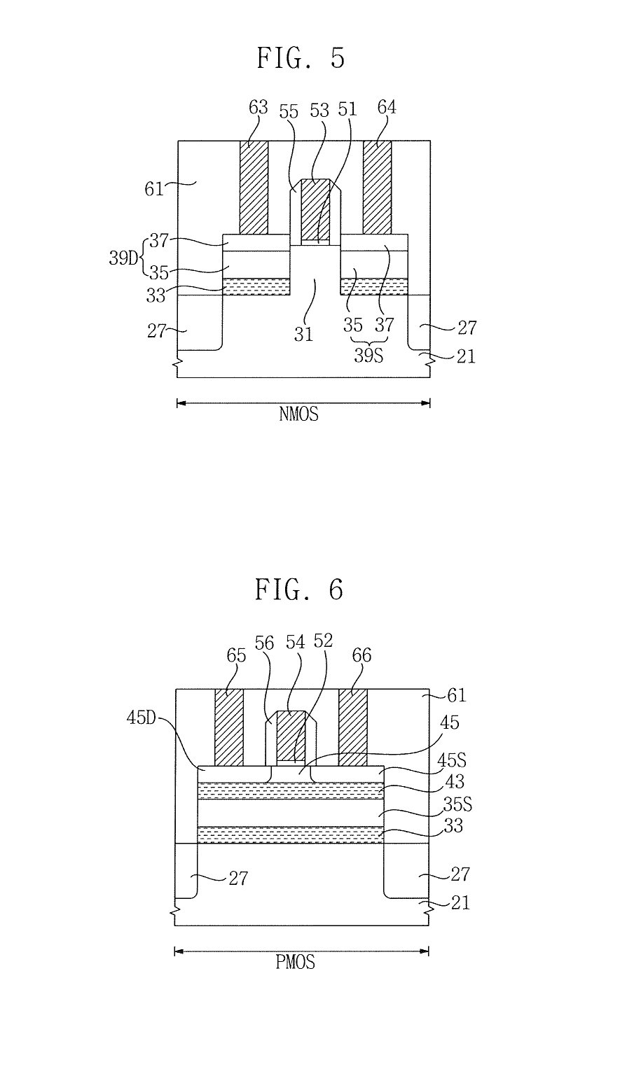

Referring to FIG. 5, an upper surface of a second semiconductor layer 37 is higher than an upper surface of a first channel 31. The upper surface of the first channel 31 is lower than upper surfaces of a first drain 39D and a first source 39S.

Referring to FIG. 6, a semiconductor device in accordance with an example embodiment of the present inventive concept includes a device isolation layer 27, a stressor 35S, an upper buffer layer 43, a second channel 45, a second drain 45D, a second source 45S, a second gate dielectric layer 52, a second gate electrode 54, a second spacer 56, an interlayer insulating layer 61, and contact plugs 65 and 66, which are formed on a substrate 21 including a PMOS region.

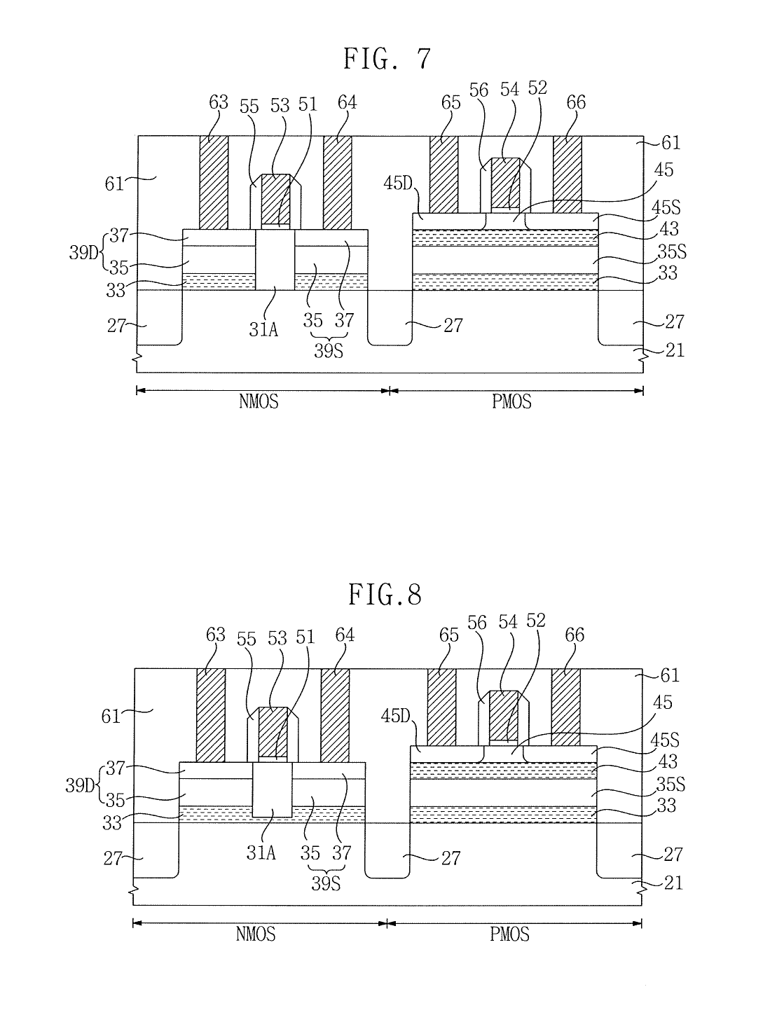

Referring to FIG. 7, a semiconductor device in accordance with an example embodiment of the inventive concept includes a device isolation layer 27, a first channel 31A, a buffer layer 33, a first drain 39D, a first source 39S, a first gate dielectric layer 51, a first gate electrode 53, a first spacer 55, a stressor 35S, a upper buffer layer 43, a second channel 45, a second drain 45D, a second source 45S, a second gate dielectric layer 52, a second gate electrode 54, a second spacer 56, an interlayer insulating layer 61, and contact plugs 63, 64, 65, and 66, which are formed on a substrate 21 including an NMOS region and a PMOS region.

Each of the first drain 39D and the first source 39S includes a first semiconductor layer 35 and a second semiconductor layer 37. The first semiconductor layer 35 and the second semiconductor layer 37 form a heterogeneous structure. The contact plugs 63, 64, 65, and 66 include a first contact plug 63, a second contact plug 64, a third contact plug 65, and a fourth contact plug 66. The first channel 31A penetrates the buffer layer 33 to be in contact with the substrate 21. The first channel 31A may include a different material from the substrate 21. The first channel 31A may include a crystal growth material.

Referring to FIG. 8, a first channel is inserted in a buffer layer 33. For example, a portion of the buffer layer 33 is interposed between a first channel 31A and a substrate 21. The buffer layer 33 surrounds a lower surface and side surfaces of the first channel 31A.

Referring to FIG. 9, a first channel 31A penetrates a buffer layer 33 and is inserted into a substrate 21. A lower surface of the first channel 31A is lower level than an upper surface of the substrate 21.

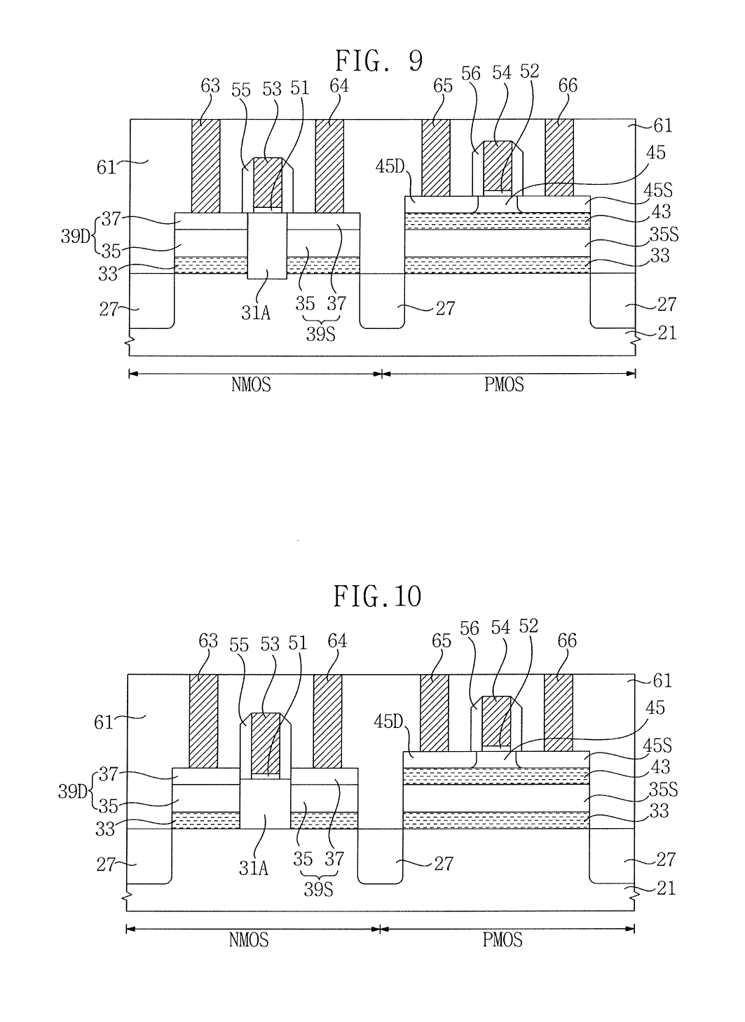

Referring to FIG. 10, an upper surface of a second semiconductor layer 37 is higher level than an upper surface of a first channel 31A. The upper surface of the first channel 31A is lower level than upper surfaces of a first drain 39D and a first source 39S. The first channel 31A may pass through the buffer layer 33 to be in contact with the substrate 21.

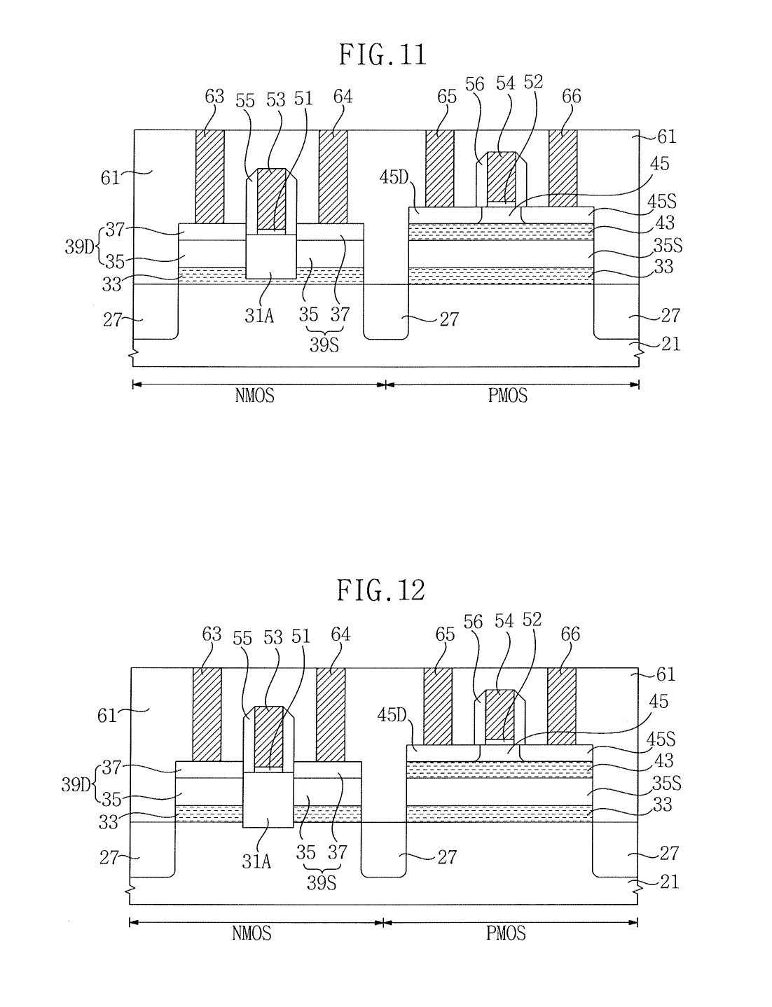

Referring to FIG. 11, an upper surface of a second semiconductor layer 37 is higher than an upper surface of a first channel 31A. A first channel 31A is inserted into a buffer layer 33. For example, a portion of the buffer layer 33 is interposed between the first channel 31A and a substrate 21. The buffer layer 33 surrounds a lower surface and side surfaces of the first channel 31A.

Referring to FIG. 12, an upper surface of a second semiconductor layer 37 is higher than an upper surface of a first channel 31A. The first channel 31A penetrates a buffer layer 33 and is inserted into a substrate 21.

Referring to FIG. 13, a semiconductor device in accordance with an example embodiment of the inventive concept includes a device isolation layer 27, a first channel 31A, a buffer layer 33, a first drain 39D, a first source 39S, a first gate dielectric layer 51, a first gate electrode 53, a first spacer 55, an interlayer insulating layer 61, and contact plugs 63 and 64, which are formed on a substrate 21 including an NMOS region. The first channel 31A penetrates the buffer layer 33 to be in contact with the substrate 21.

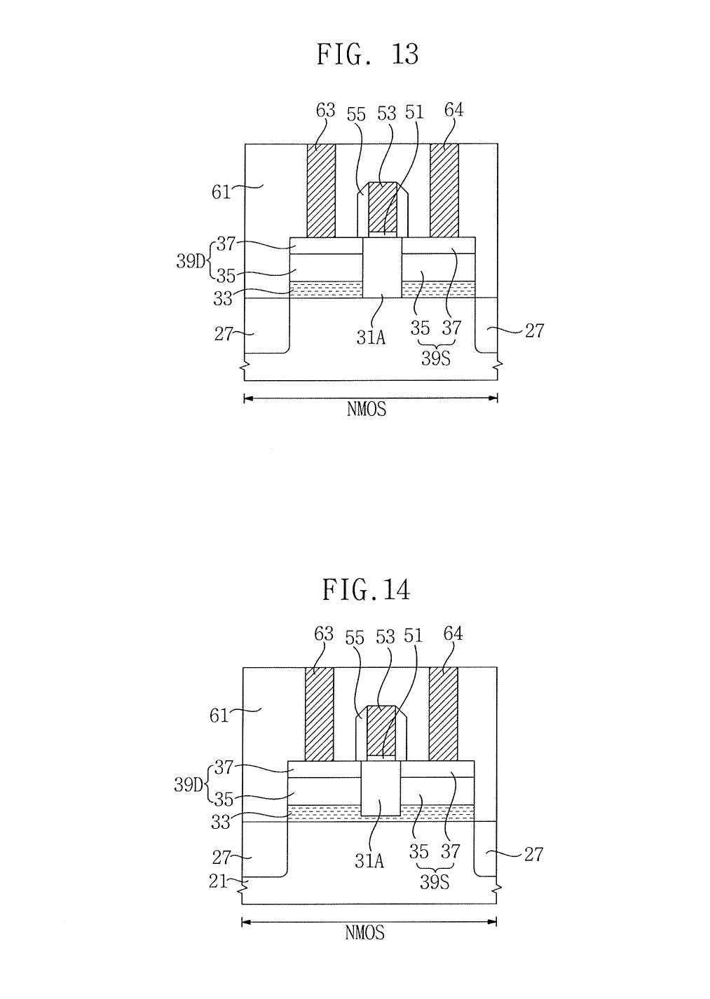

Referring to FIG. 14, a first channel 31A is inserted into a buffer layer 33. For example, a portion of the buffer layer 33 is interposed between the first channel 31A and a substrate 21.

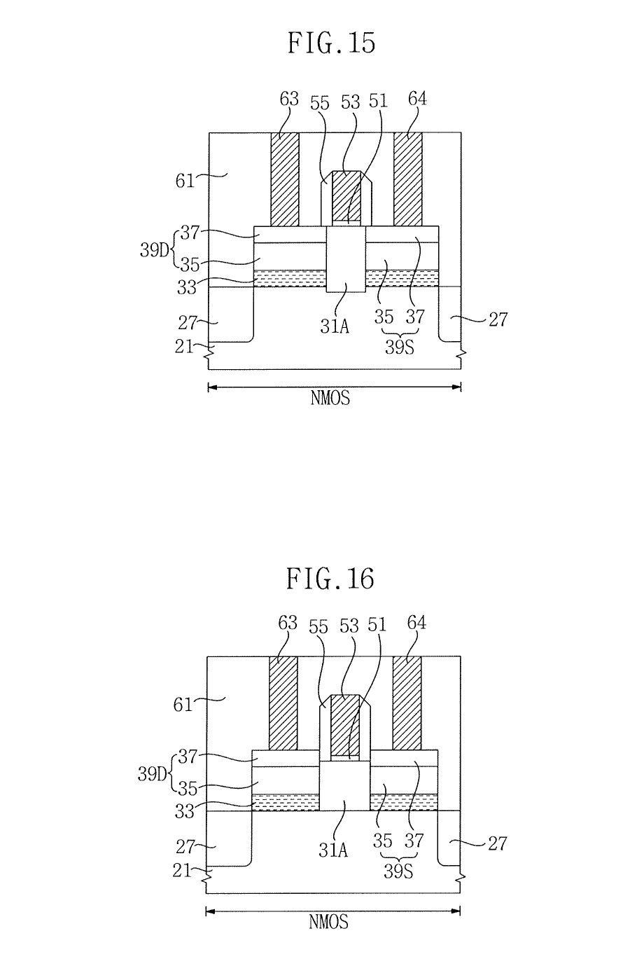

Referring to FIG. 15, a first channel 31A penetrates the buffer layer 33 and is inserted into a substrate 21.

Referring to FIG. 16, an upper surface of a second semiconductor layer 37 is higher than an upper surface of a first channel 31A. The first channel 31A penetrates a buffer layer 33 to be in contact with a substrate 21.

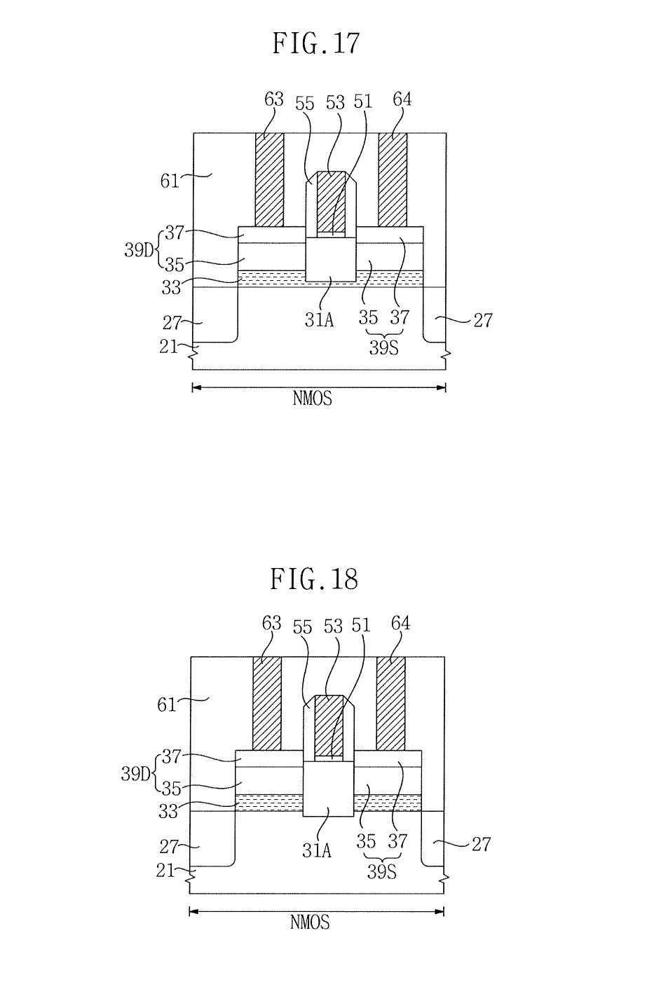

Referring to FIG. 17, an upper surface of a second semiconductor layer 37 is higher than an upper surface of a first channel 31A. A first channel 31A is inserted into a buffer layer 33. For example, a portion of the buffer layer 33 is interposed between the first channel 31A and a substrate 21.

Referring to FIG. 18, an upper surface of a second semiconductor layer 37 is higher than an upper surface of a first channel 31A. The first channel 31A penetrates a buffer layer 33 and is inserted into a substrate 21.

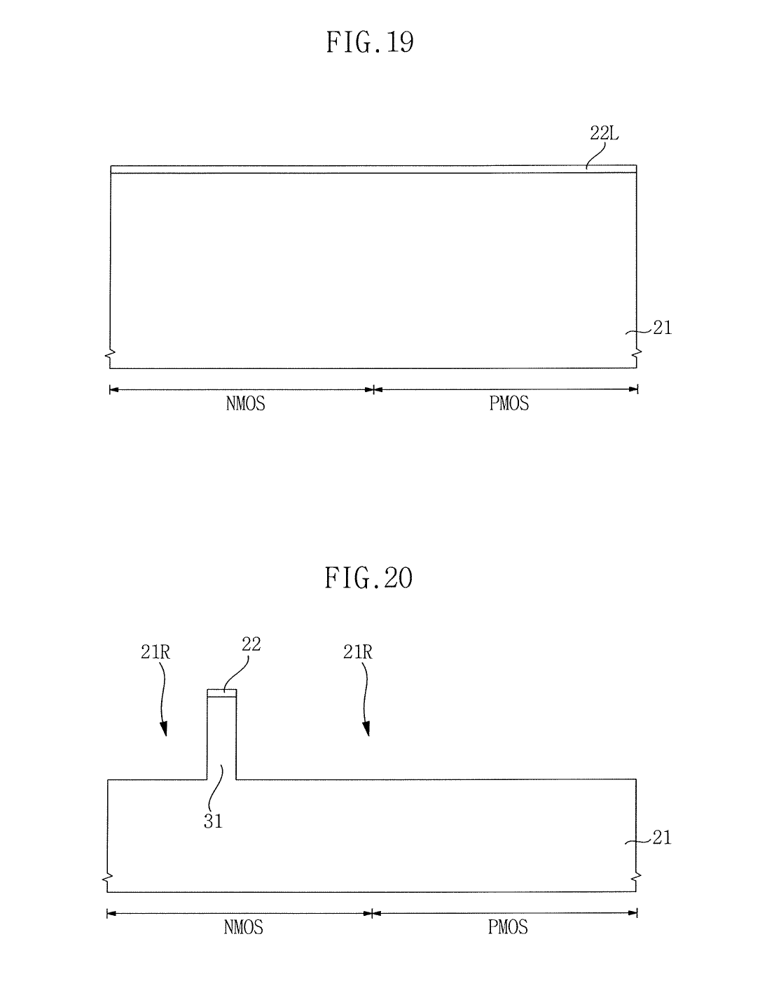

FIGS. 19 to 24 are cross-sectional views of a method of forming a semiconductor device in accordance with an example embodiment of the inventive concept.

Referring to FIG. 19, a pad layer 22L is formed on a substrate 21 including an NMOS region and a PMOS region. The pad layer 22L may include an insulating layer such as silicon oxide.

Referring to FIG. 20, a pad pattern 22 and recess areas 21R is formed by patterning the pad layer 22L and the substrate 21. A first channel 31 is formed on the recessed substrate 21 by the recess areas 21R.

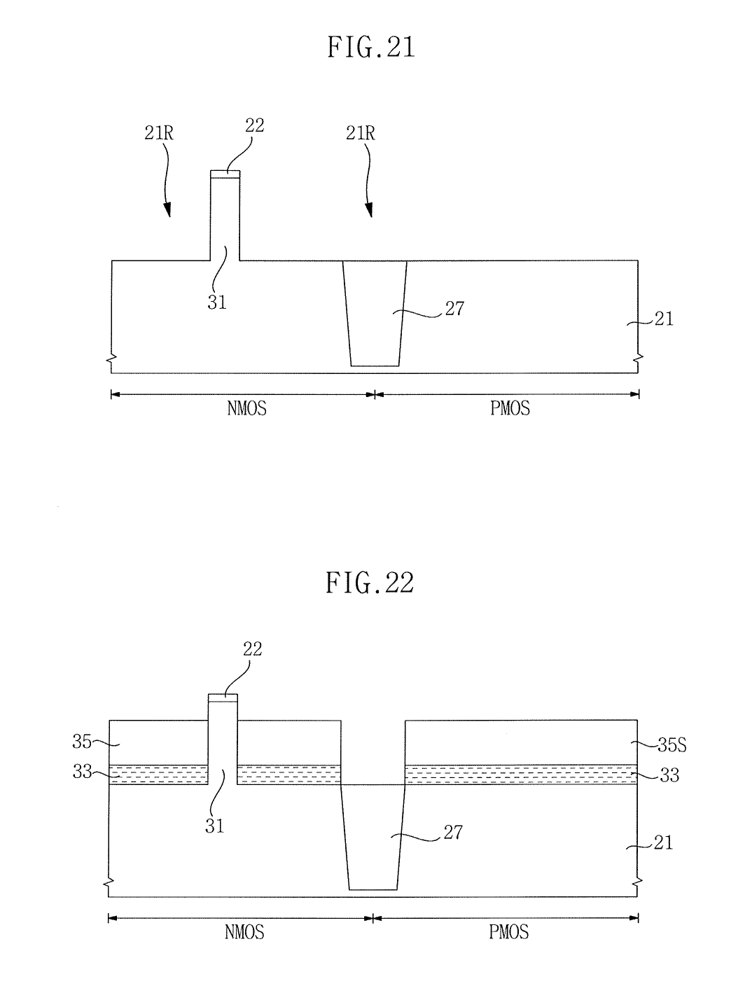

Referring to FIG. 21, a device isolation layer 27 is formed in the substrate 21.

Referring to FIG. 22, a buffer layer 33 is formed. A first semiconductor layer 35 and a stressor 35S are formed on the buffer layer 33.

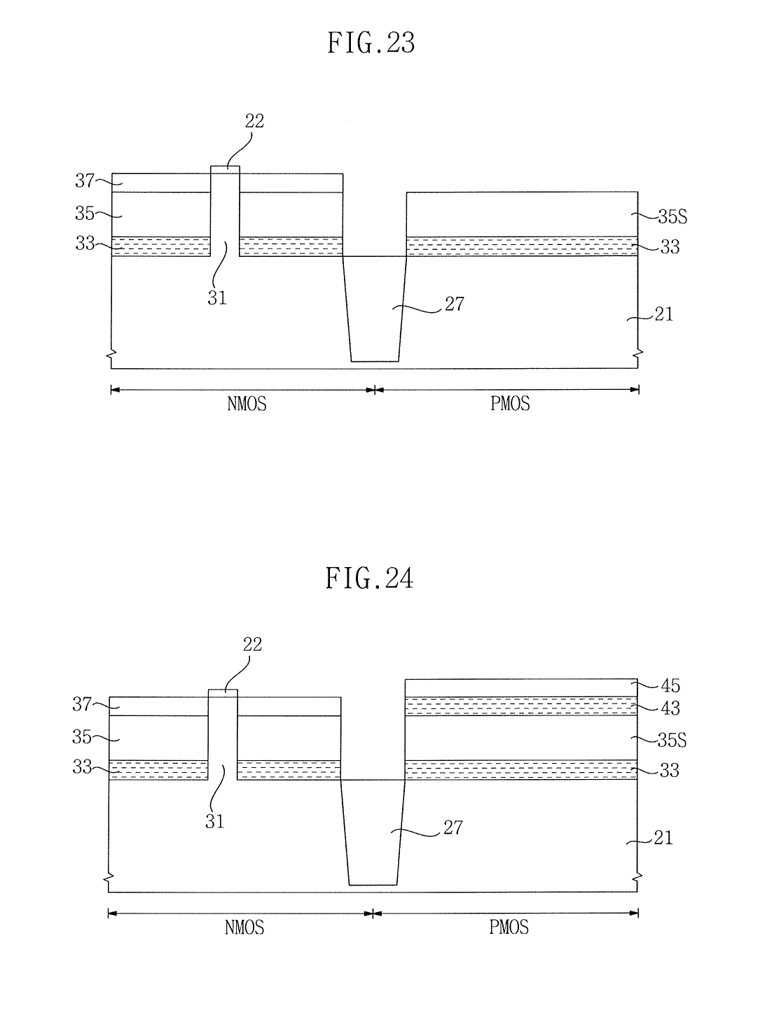

Referring to FIG. 23, a second semiconductor layer 37 may be formed on the first semiconductor layer 35. The first semiconductor layer 35 and the second semiconductor layer 37 may configure a heterogeneous structure.

Referring to FIG. 24, an upper buffer layer 43 is formed on the stressor 35S. A second channel 45 is formed on the upper buffer layer 43.

Referring again to FIG. 1, the pad pattern 22 may be removed. The first semiconductor layer 35 and the second semiconductor layer 37 formed at one side of the first channel 31 may change a first drain 39D through a first doping process of impurities. The first semiconductor layer 35 and the second semiconductor layer 37 formed at the other side of the first channel 31 may change to a first source 39S through a second doping process. The doping processes may include a diffusion process and/or ion implantation process of impurities. A first gate dielectric layer 51, a first gate electrode 53, a second drain 45D, a second source 45S, a second gate dielectric layer 52, a second gate electrode 54, and contact plugs 63, 64, 65, and 66 may be formed. The contact plugs 63, 64, 65, and 66 include a first contact plug 63, a second contact plug 64, a third contact plug 65, and a fourth contact plug 66.

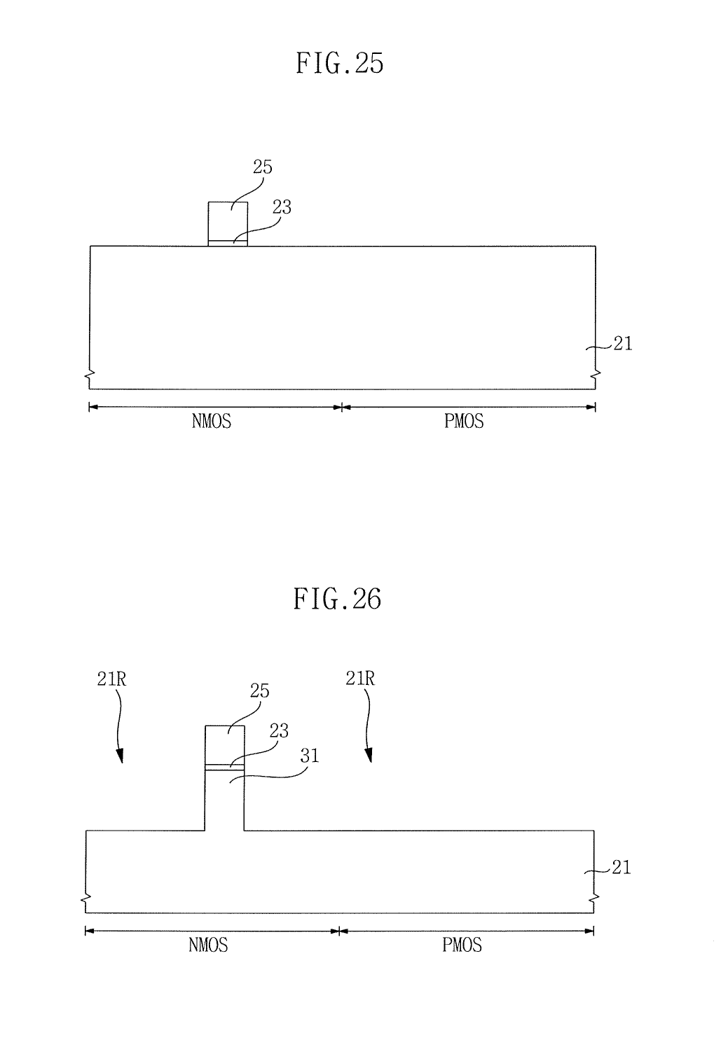

FIGS. 25 to 34 are cross-sectional views of a method of forming a semiconductor device in accordance with an example embodiment of the inventive concept.

Referring to FIG. 25, a pad pattern 23 and a hardmask pattern 25 are formed on a substrate 21 including an NMOS region and a PMOS region. The substrate 21 may be a single crystalline silicon wafer containing p-type impurities. The pad pattern 23 and the hardmask pattern 25 are formed in the NMOS region. For example, the pad pattern 23 may include an insulating material such as silicon oxide. The hardmask pattern 25 may include a material having etch selectivity with respect to the substrate 21. For example, the hardmask pattern 25 may include silicon nitride, silicon oxide, polysilicon, or a combination thereof. The pad pattern 23 and the hardmask pattern 25 may be formed using a thin-film formation process and a patterning process.

Referring to FIG. 26, the substrate 21 may be partially etched using the hardmask pattern 25 as an etch mask, to form recess areas 21R. A first channel 31 may be defined on the substrate 21 by the recess areas 21R. The first channel 31 may be formed in the NMOS region. The first channel 31 may correspond to a portion of the substrate 21. The first channel 31 includes single crystalline silicon containing p-type impurities.

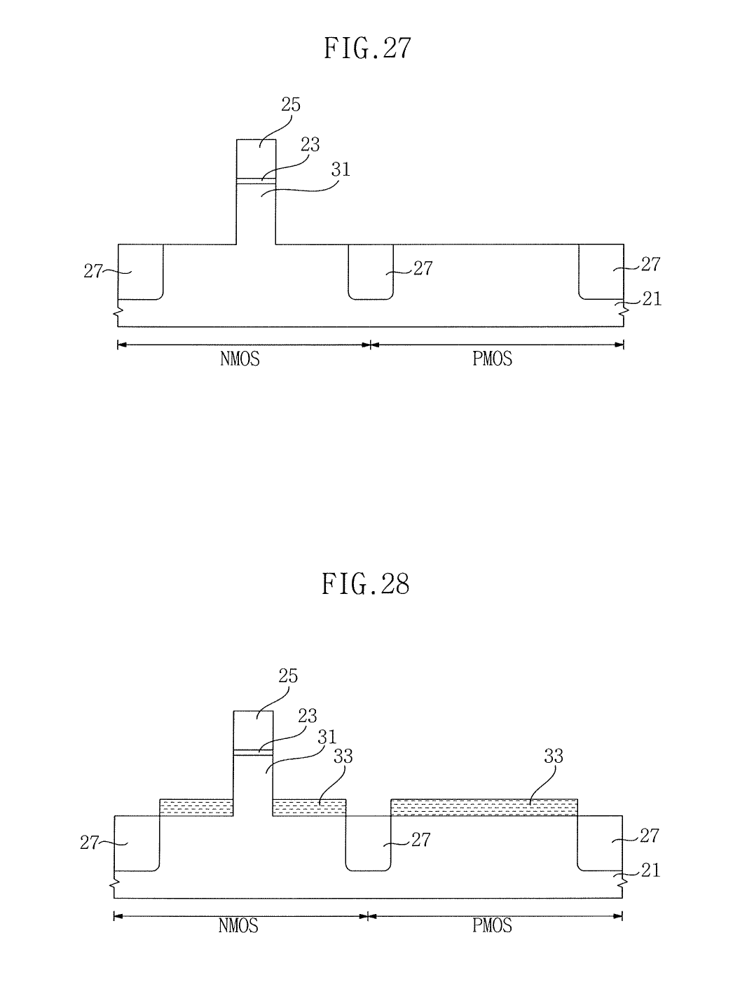

Referring to FIG. 27, a device isolation layer 27 is formed in the substrate 21. The device isolation layer 27 may be formed using a shallow trench isolation (STI) method. The device isolation layer 27 may include an insulating material, such as silicon oxide, silicon nitride, silicon oxy-nitride, or a combination thereof.

Referring to FIG. 28, a buffer layer 33 is formed. The buffer layer 33 may include a crystal growth material. For example, the buffer layer 33 may be selectively formed on the substrate 21 located at both sides of the first channel 31 using a crystal growth method such as an epitaxial growth method, for example. The buffer layer 33 may be formed at a lower level than an upper surface of the first channel 31. Side surfaces of the first channel 31 located at a higher level than the buffer layer 33 are exposed.

The buffer layer 33 may include an AlₓGa₁₋ₓN (0<X≦1) graded structure with an Al content increasing downwardly toward the substrate 21 and decreasing upwardly toward an upper surface of the buffer layer 33. For example, the buffer layer 33 may include sequentially stacked first to sixth layers. A first layer of the buffer layer 33 may be an AlN layer and be the lowermost layer which is in contact with the substrate 21. A second layer of the buffer layer 33 may be an AlₓGa₁₋ₓN (0.7≦X≦1) layer and formed on the first layer. A third layer of the buffer layer 33 may be an AlₓGa₁₋ₓN (0.5≦X<0.7) layer and formed on the second layer. A fourth layer of the buffer layer 33 may be an AlₓGa₁₋ₓN (0.3≦X<0.5) layer and formed on the third layer. A fifth layer of the buffer layer 33 may be an AlₓGa₁₋ₓN (0.05≦X<0.3) layer and formed on the fourth layer. A sixth layer of the buffer layer 33 may be an AlₓGa₁₋ₓN (0<X<0.05) layer and formed on the fifth layer.

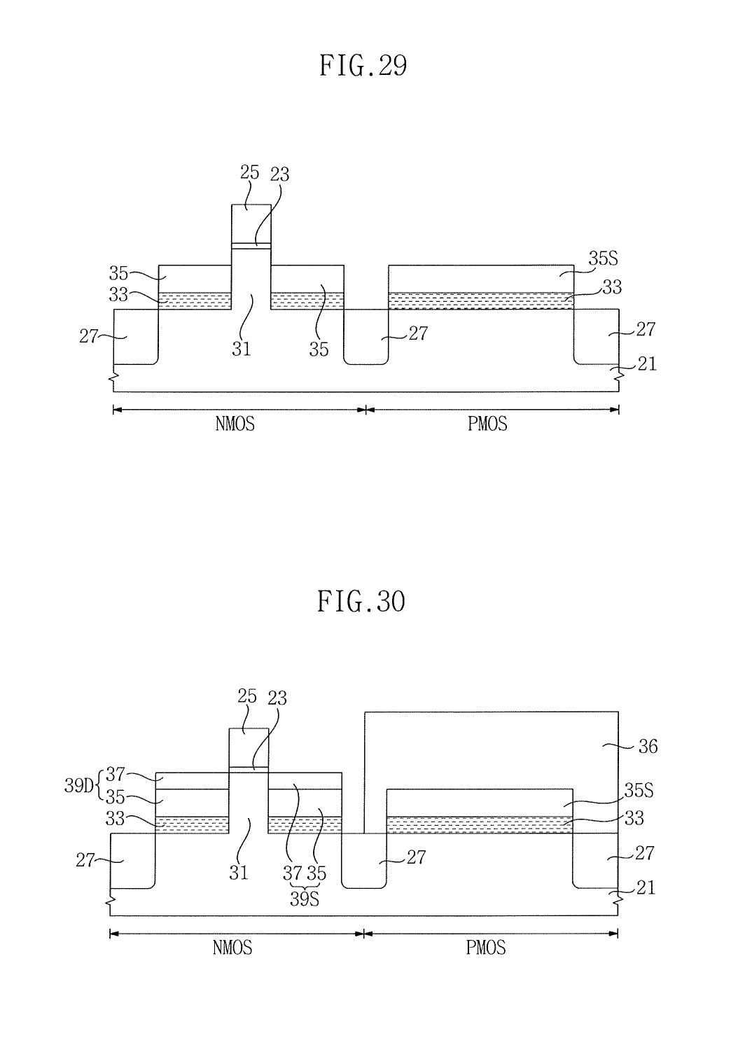

Referring to FIG. 29, a first semiconductor layer 35 and a stressor 35S are formed on the buffer layer 33. The first semiconductor layer 35 is formed in the NMOS region. The stressor 35S is formed in the PMOS region. The first semiconductor layer 35 and the stressor 35S may be simultaneously formed using the same process.

The first semiconductor layer 35 and the stressor 35S may include substantially the same material. The first semiconductor layer 35 and the stressor 35S may include a material having a smaller lattice constant than the first channel 31. For example, the first semiconductor layer 35 and the stressor 35S may include GaN. The first semiconductor layer 35 is in contact with a side surface of the first channel 31. The first semiconductor layer 35 and the stressor 35S are thicker than the buffer layer 33.

Referring to FIG. 30, a first mask pattern 36 covering the PMOS region and exposing the NMOS region is formed. A second semiconductor layer 37 is formed on the first semiconductor layer 35. The second semiconductor layer 37 may include a different material from the first semiconductor layer 35. For example, the second semiconductor layer 37 may include AlGaN. The first semiconductor layer 35 and the second semiconductor layer 37 constitutes a heterogeneous structure. The first semiconductor layer 35 and the second semiconductor layer 37 formed at one side of the first channel 31 may change to a first drain 39D through a doping process or an ion implantation process. The first semiconductor layer 35 and the second semiconductor layer 37 formed at the other side of the first channel 31 may change to a first source 39S through a doping process or an ion implantation process.

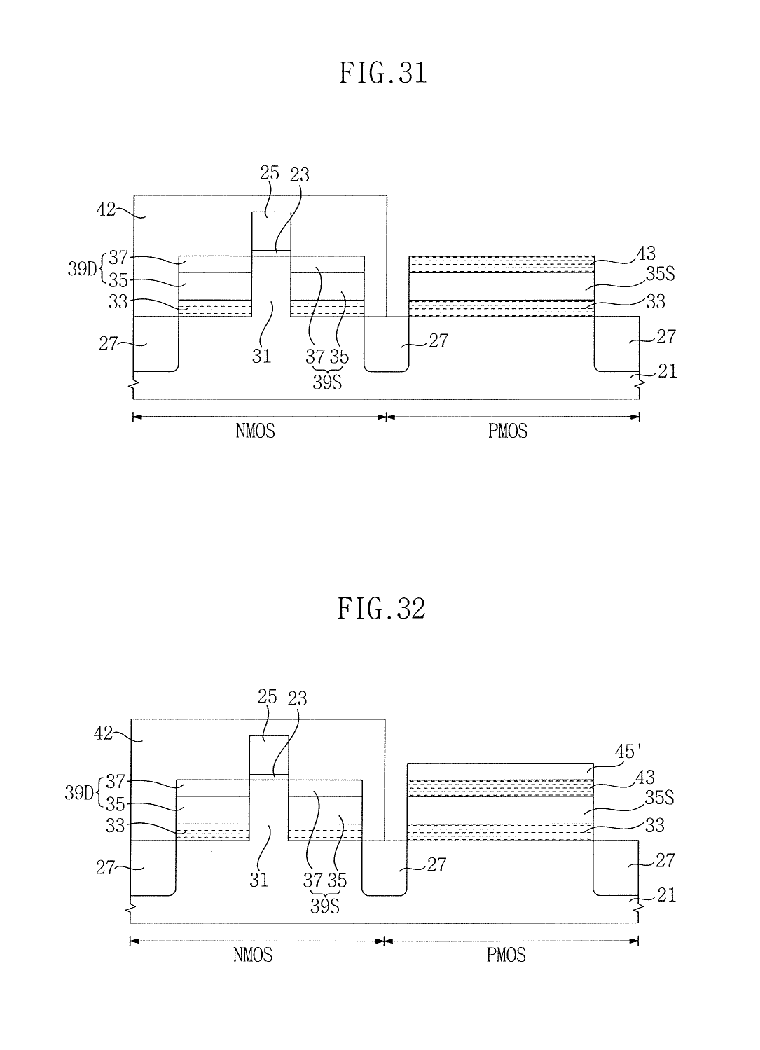

Referring to FIG. 31, the first mask pattern 36 is removed. A second mask pattern 42 covering the NMOS region and exposing the PMOS region is formed. An upper buffer layer 43 is formed on the stressor 35S. The upper buffer layer 43 is thinner than the stressor 35S. The upper buffer layer 43 may be formed using a method similar to the method of forming the buffer layer 33. The upper buffer layer 43 may include an AlₓGa₁₋ₓN (0<X≦1) graded structure with an Al content increasing downwardly toward the stressor 35S and decreasing upwardly toward an upper surface of the upper buffer layer 43.

Referring to FIG. 32, a preliminary second channel 45′ is formed on the upper buffer layer 43. The preliminary second channel 45′ may include a different semiconductor layer from the stressor 35S. The preliminary second channel 45′ may include a semiconductor layer having a greater lattice constant than the stressor 35S. The second channel 45 may include a different material from the substrate 21. For example, the second channel 45 may include a Ge layer containing n-type impurities.

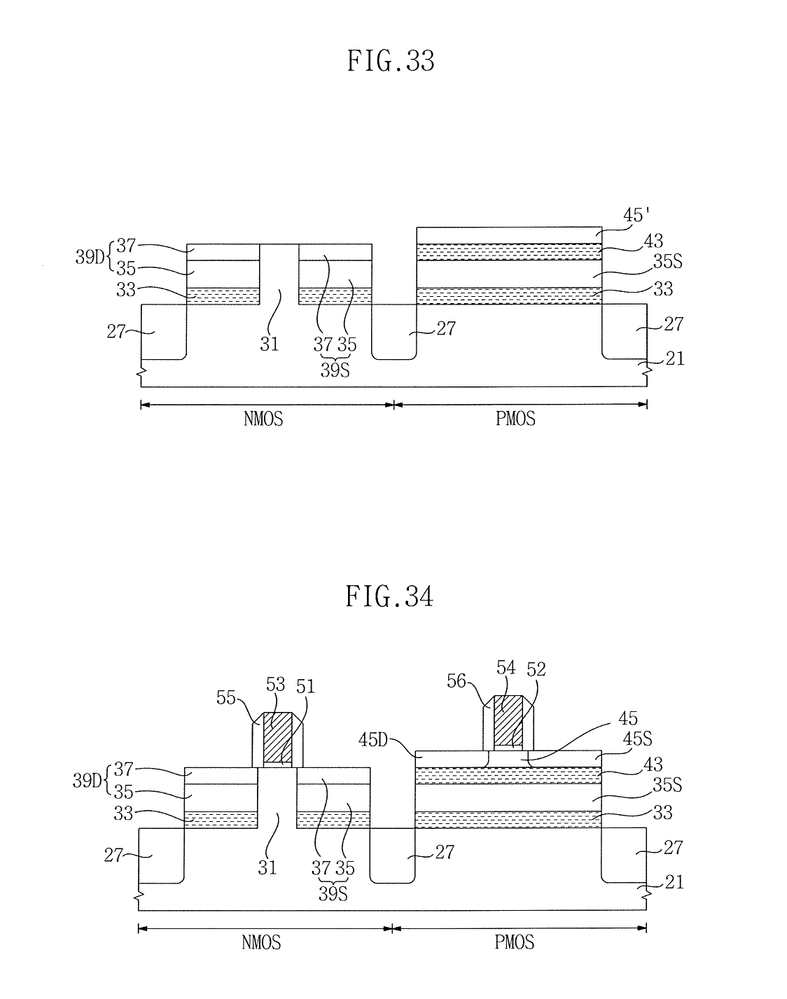

Referring to FIG. 33, the second mask pattern 42 is removed. The pad pattern 23 and the hardmask pattern 25 are removed. The preliminary second channel 45′ remain after the removal of the pad pattern 23 and the hardmask pattern 25.

Referring to FIG. 34, a first gate dielectric layer 51, a first gate electrode 53, and a first spacer 55 are formed on the first channel 31. A second gate dielectric layer 52, a second gate electrode 54, and a second spacer 56 are formed on a second channel 45. The second drain 45D and the second source 45S are formed in the preliminary second channel 45′ of FIG. 33. The second channel 45 is disposed between the second drain 45D and the second source 45S. The second drain 45D and the second source 45S are disposed in regions adjacent to sides of the second gate electrode 54.

The first gate dielectric layer 51 may include silicon oxide, silicon nitride, silicon oxynitride, a high-k dielectric, or a combination thereof. The first gate electrode 53 may include a metal, a metal nitride, a metal oxide, a metal silicide, polysilicon, conductive carbon, or a combination thereof. The first spacer 55 may include silicon oxide, silicon nitride, silicon oxynitride, or a combination thereof.

The second drain 45D and the second source 45S may include a Ge layer containing p-type impurities. The second gate dielectric layer 52 may include silicon oxide, silicon nitride, silicon oxynitride, a high-k dielectric, or a combination thereof. The second gate electrode 54 may include a metal, a metal nitride, a metal oxide, a metal silicide, polysilicon, conductive carbon, or a combination thereof. The second spacer 56 may include silicon oxide, silicon nitride, silicon oxynitride, or a combination thereof.

Referring back to FIG. 2, an interlayer insulating layer 61 and contact plugs 63, 64, 65, and 66 may be formed. The contact plugs 63, 64, 65, and 66 include a first contact plug 63, a second contact plug 64, a third contact plug 65, and a fourth contact plug 66. The interlayer insulating layer 61 may include silicon oxide, silicon nitride, silicon oxynitride, a low-k dielectric, or a combination thereof. The contact plugs 63, 64, 65, and 66 may include a metal layer, a metal nitride layer, a metal oxide layer, a metal silicide layer, a polysilicon layer, a semiconductor layer, an ohmic contact layer, or a combination thereof.

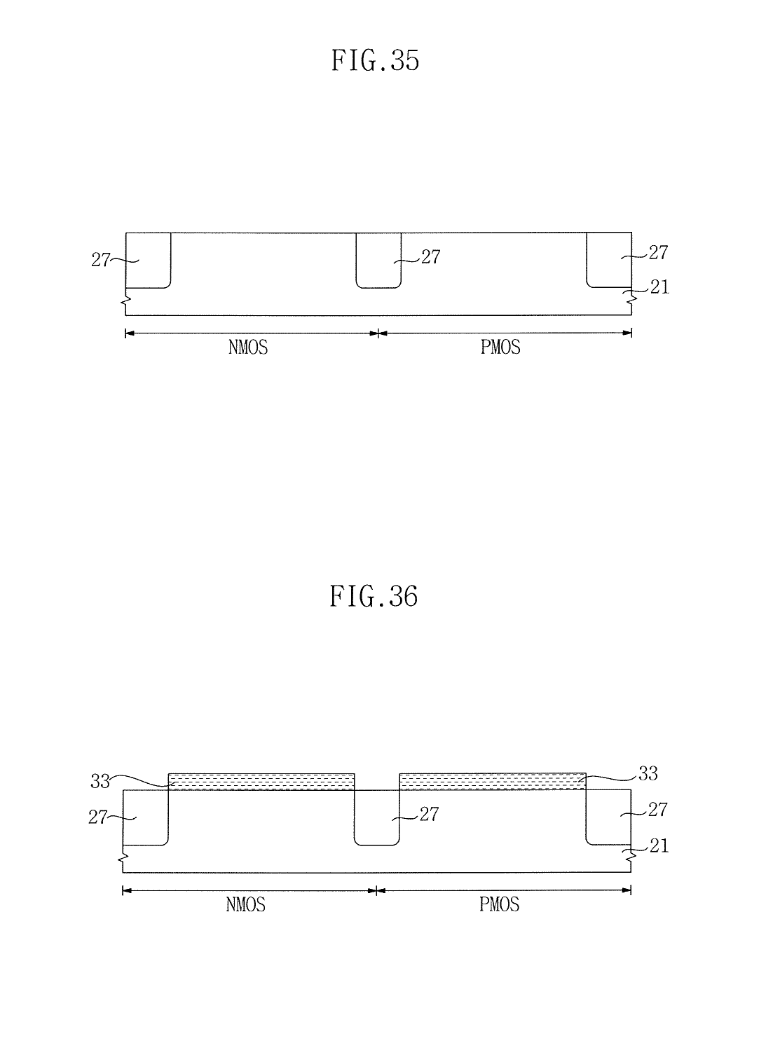

FIGS. 35 to 43 may be cross-sectional views of a method of forming a semiconductor device in accordance with an example embodiment of the inventive concept.

Referring to FIG. 35, a device isolation layer 27 is formed in a substrate 21 including an NMOS region and a PMOS region.

Referring to FIG. 36, a buffer layer 33 is formed.

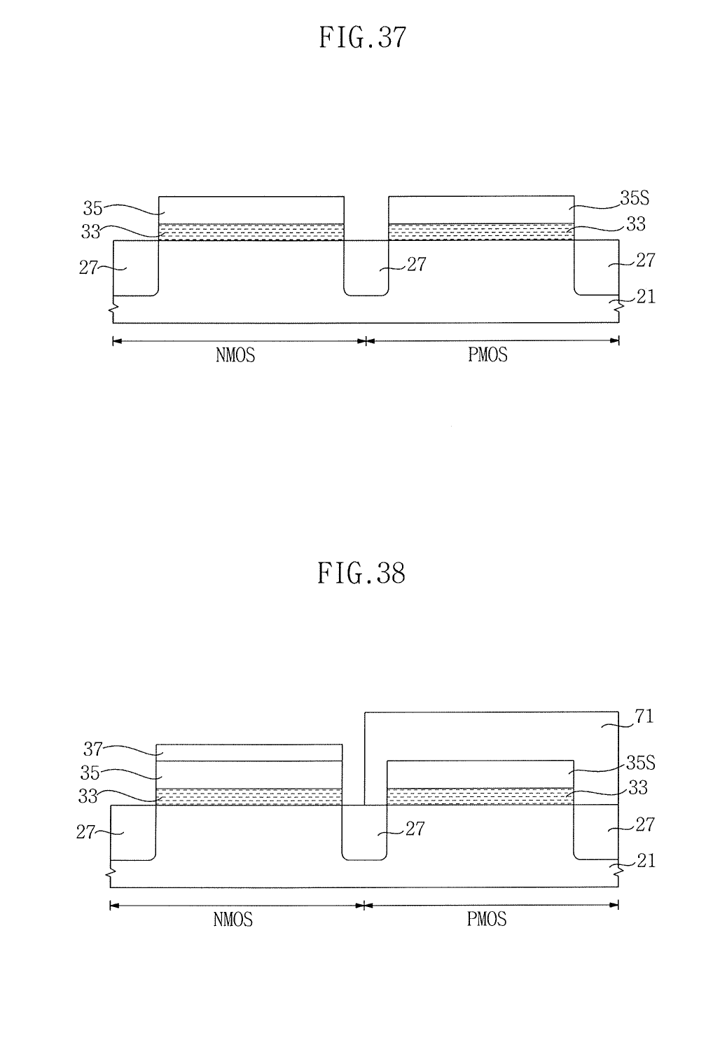

Referring to FIG. 37, a first semiconductor layer 35 and a stressor 35S are formed on the buffer layer 33.

Referring to FIG. 38, a first mask pattern 71 covering the PMOS region and exposing the NMOS region is formed. A second semiconductor layer 37 is formed on the first semiconductor layer 35.

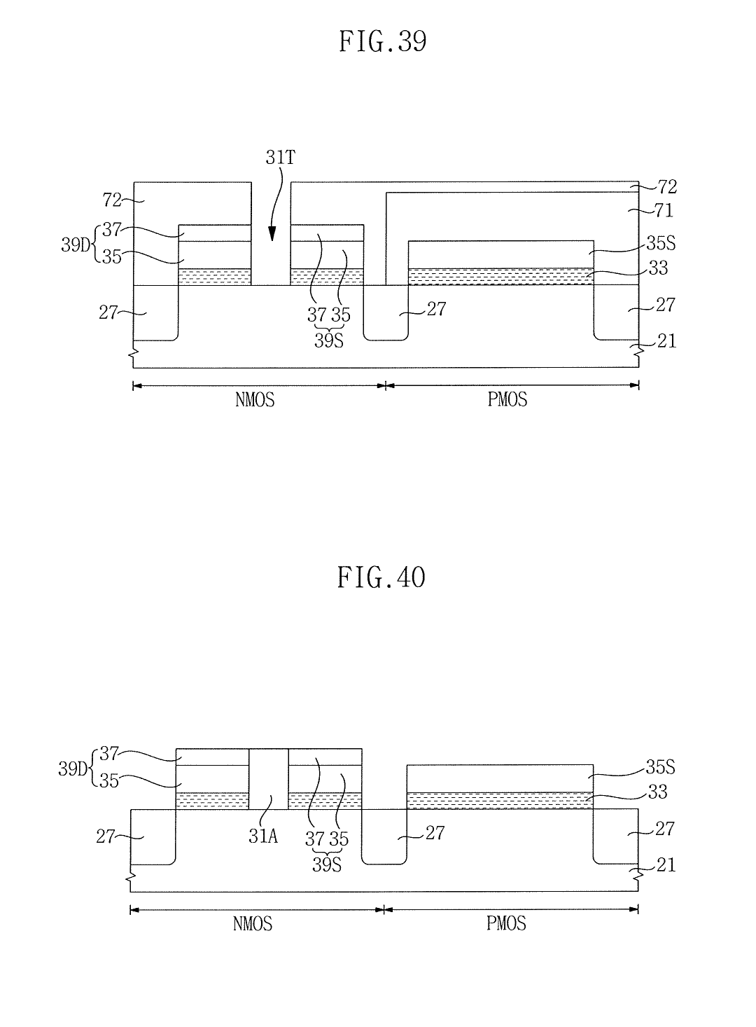

Referring to FIG. 39, a second mask pattern 72 is formed. A channel trench 31T is formed by patterning the second semiconductor layer 37, the first semiconductor layer 35, and the buffer layer 33. The first semiconductor layer 35 and the second semiconductor layer 37 formed at one side of the channel trench 31T may change to a first drain 39D through a doping and/or an ion implantation process. The first semiconductor layer 35 and the second semiconductor layer 37 formed at the other side of the channel trench 31T may change to a first source 39S through a doping and/or an ion implantation process. The substrate 21 is exposed through the channel trench 31T.

Referring to FIG. 40, a first channel 31A is formed in the channel trench 31T. The first mask pattern 71 and the second mask pattern 72 are removed.

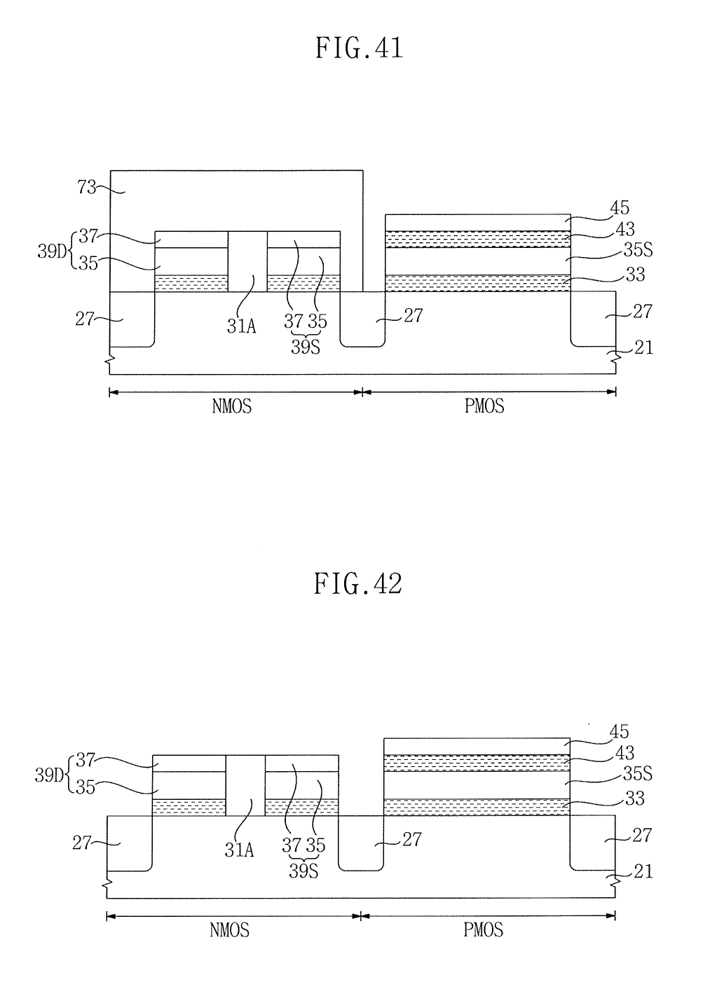

Referring to FIG. 41, a third mask pattern 73 covering the NMOS region and exposing the PMOS region is formed. An upper buffer layer 43 is formed on the stressor 35S. A preliminary second channel 45′ is formed on the upper buffer layer 43.

Referring to FIG. 42, the third mask pattern 73 is removed.

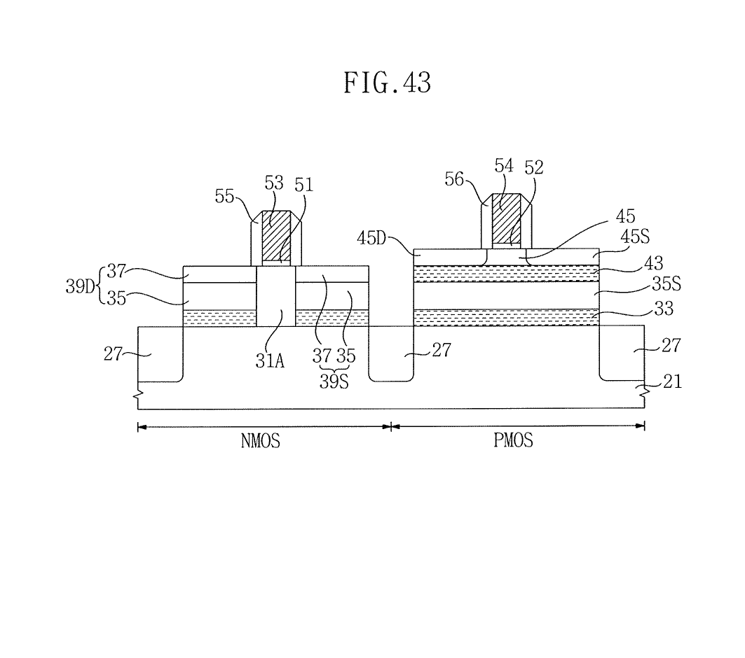

Referring to FIG. 43, a first gate dielectric layer 51, a first gate electrode 53, and a first spacer 55 are formed. A second drain 45D, a second source 45S, a second gate dielectric layer 52, a second gate electrode 54, and a second spacer 56 are foil led.

Referring again to FIG. 7, an interlayer insulating layer 61 and contact plugs 63, 64, 65, and 66 may be formed. The contact plugs 63, 64, 65, and 66 include a first contact plug 63, a second contact plug 64, a third contact plug 65, and a fourth contact plug 66.

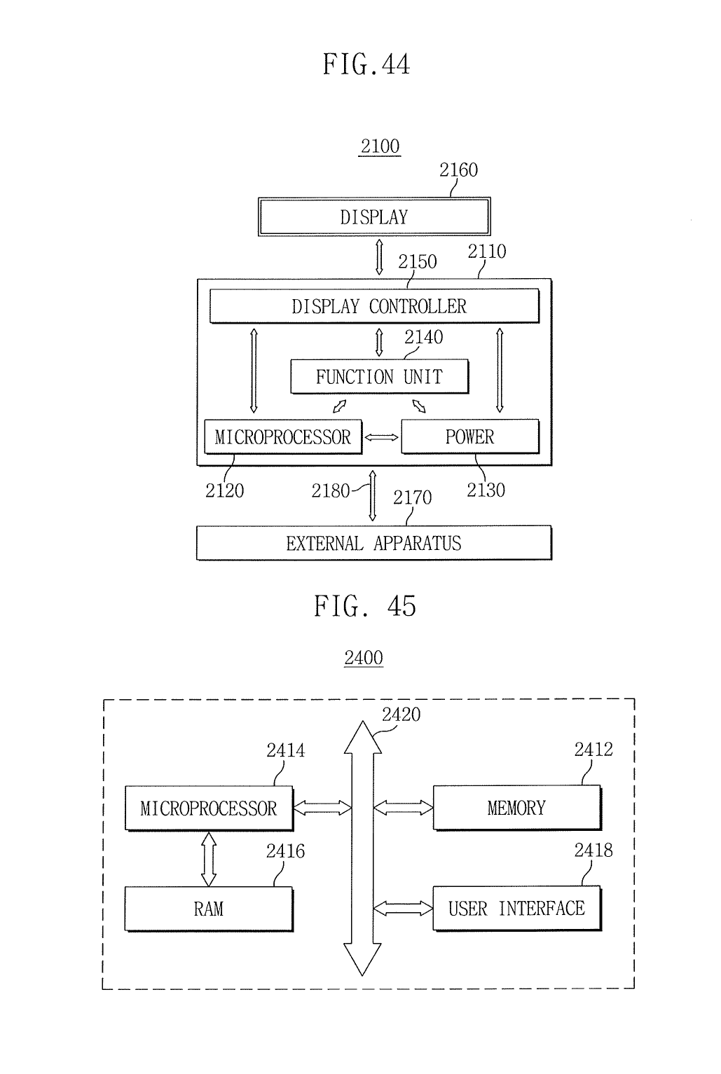

FIGS. 44 and 45 are system block diagrams of electronic apparatuses in accordance with example embodiments of the inventive concept.

Referring to FIG. 44, an electronic system 2100 may include a semiconductor device according to an example embodiment of the present inventive concept. The electronic system 2100 includes a body 2110, a microprocessor 2120, a power unit 2130, a function unit 2140, and a display controller 2150. The body 2110 may be a motherboard formed of a printed circuit board (PCB). The microprocessor 2120, the power unit 2130, the function unit 2140, and the display controller 2150 may be installed on the body 2110. A display 2160 may be disposed inside or outside the body 2110. For example, the display 2160 may be disposed on a surface of the body 2110 and display an image processed by the display controller 2150.

The power unit 2130 may receive a constant voltage from an external battery, etc., divide the voltage into various levels of voltages, and supply those voltages to the microprocessor 2120, the function unit 2140, and the display controller 2150, etc. The microprocessor 2120 may receive a voltage from the power unit to control the function unit 2140 and the display 2160. The function unit 2140 may perform various functions of the electronic system 2100. For example, if the electronic system 2100 is a smartphone, the function unit 2140 may have several components which perform functions of the mobile phone such as output of an image to the display 2160 or output of a voice to a speaker, by dialing or communication with an external apparatus 2170. If a camera is installed, the function unit 2140 may function as a camera image processor.

If the electronic system 2100 is connected to a memory card, etc. to expand a capacity thereof, the function unit 2140 may be a memory card controller. The function unit 2140 may exchange signals with the external apparatus 2170 through a wired or wireless communication unit 2180. Further, if the electronic system 2100 needs a Universal Serial Bus (USB), etc. to expand functionality, the function unit 2140 may function as an interface controller. Further, the function unit 2140 may include a mass storage apparatus.

The function unit 2140 and/or the microprocessor 2120 may include a semiconductor device according to an example embodiment. For example, the microprocessor 2120 may include the buffer layer 33, the first drain 39D, and the stressor 35S in FIG. 1, for example.

Referring to FIG. 45, an electronic system 2400 includes at least one semiconductor device in accordance with example embodiments of the present inventive concept. The electronic system 2400 may include a mobile apparatus or a computer. For example, the electronic system 2400 includes a memory system 2412, a microprocessor 2414, a random access memory (RAM) 2416, a bus 2420, and a user interface 2418. The microprocessor 2414, the memory system 2412, and the user interface 2418 may be interconnected via the bus 2420. The user interface 2418 may be used to input data to or output data from the electronic system 2400. The microprocessor 2414 may program and control the electronic system 2400. The RAM 2416 may be used as an operational memory of the microprocessor 2414. The microprocessor 2414, the RAM 2416, and/or other components may be assembled in a single package. The memory system 2412 may store codes for operating the microprocessor 2414, data processed by the microprocessor 2414, or external input data. The memory system 2412 may include a controller and a memory device.

The microprocessor 2414, the RAM 2416, and the memory system 2412 may include a semiconductor device according to an example embodiment.

According to example embodiments of the present inventive concept, a first drain and a first source having a heterogeneous structure and spaced apart from each other may be formed on a buffer layer in an NMOS region. A first channel may be formed between the first drain and the first source. A stressor may be formed on a buffer layer in a PMOS region. An upper buffer layer may be formed on the stressor. A second channel, a second drain, and a second source may be formed on the upper buffer layer. Electron mobility may increase due to the configuration of the first channel, the first drain, and the first source. Hole mobility may increase due to the configuration of the second channel, the second drain, the second source, and the stressor. The buffer layer and the upper buffer layer may function to prevent generation of cracks. The performance of a semiconductor device may increase according to an example embodiment.

While the present inventive concept has been shown and described with reference to example embodiments thereof, it will be apparent to those of ordinary skill in the art that various changes in form and detail may be made therein without departing from the spirit and scope of the inventive concept as defined by the following claims.

1. A semiconductor device, comprising:
a substrate including an NMOS region and a PMOS region;
a first buffer layer on the substrate;
a first drain and a first source disposed on the first buffer layer and spaced apart from each other, wherein each of the first drain and the source has a heterogeneous structure;
a first channel between the first drain and the first source;
a first gate electrode on the first channel;
a second drain and a second source disposed on the first buffer layer and spaced apart from each other;
a second channel disposed between the second drain and the second source and including a different material from the first channel; and
a second gate electrode on the second channel,
wherein the first drain, the first source, the first channel, and the first gate electrode are disposed in the NMOS region, and
the second drain, the second source, the second channel, and the second gate electrode are disposed in the PMOS region.

2. The semiconductor device of claim 1, wherein the first buffer layer includes a AlₓGa₁₋ₓN (0<X≦1) graded structure with an Al content increasing downwardly toward the substrate and decreasing upwardly toward each of the first drain and the first source.

3. The semiconductor device of claim 1, wherein the first channel includes a different semiconductor layer from the first drain and the first source.

4. The semiconductor device of claim 1, wherein the first channel penetrates the first buffer layer to contact the substrate.

5. The semiconductor device of claim 1, wherein the first channel and the substrate include single crystalline silicon having p-type impurities.

6. The semiconductor device of claim 1, wherein a portion of the first buffer layer is interposed between the substrate and the first channel.

7. The semiconductor device of claim 1, wherein each of the first drain and the first source includes a layered structure of a first semiconductor layer and a second semiconductor layer, and
the first semiconductor layer is in contact with the first channel and the first buffer layer.

8. The semiconductor device of claim 7, wherein an upper surface of the first channel is higher than an upper surface of the first semiconductor layer.

9. The semiconductor device of claim 7, wherein the second semiconductor layer is in contact with the first channel.

10. The semiconductor device of claim 7, wherein an upper surface of the first channel is lower than an upper surface of the second semiconductor layer.

11. The semiconductor device of claim 7, wherein a lower surface of the first gate electrode is lower than an upper surface of the second semiconductor layer.

12. The semiconductor device of claim 7, wherein the first semiconductor layer includes GaN, and the second semiconductor layer includes AlGaN.

13. The semiconductor device of claim 7, further comprising:
a stressor between the first buffer layer and the second channel; and
a second buffer layer between the stressor and the second channel,
wherein the stressor includes the same material as the first semiconductor layer.

14. The semiconductor device of claim 13, wherein the stressor has substantially the same thickness as the first semiconductor layer.

15. The semiconductor device of claim 13, wherein the stressor is interposed between the first buffer layer and the second buffer layer.

16. The semiconductor device of claim 13, wherein the second buffer layer includes an AlₓGa₁₋ₓN (0<X≦1) graded structure with an Al content increasing downwardly toward the stressor and decreasing upwardly toward each of the second channel, the second drain and the second source.

17. The semiconductor device of claim 13, wherein the second channel includes a different semiconductor layer from the stressor.

18. The semiconductor device of claim 13, wherein the second channel includes a Ge layer having n-type impurities, and each of the second drain and the second source includes a Ge layer having p-type impurities.

19. A semiconductor device, comprising:
a buffer layer on a substrate;
a drain and a source disposed on the buffer layer and spaced apart from each other, wherein each of the drain and the source is a heterogeneous structure;
a channel disposed between the drain and the source and including a different semiconductor material from the drain and the source; and
a gate electrode on the channel.

20.-34. (canceled)

35. A semiconductor device, comprising:
a substrate including an NMOS region and a PMOS region;
a first buffer layer in the NMOS region and the PMOS region;
a second buffer layer in the PMOS region only;
a first transistor on a first portion of the first buffer layer, wherein the first portion is disposed in the NMOS region; and
a second transistor on the second buffer layer,
wherein the first transistor includes a first source/drain having a layered, heterogeneous structure and the second transistor includes a second source/drain, and wherein an upper surface of the first source/drain is higher than an upper surface of the second source/drain.

36.-40. (canceled)
